(19) United States
(12) Patent Application Publication
(10) Pub. No.: US 2023/0189504 A1
(43) Pub. Date: Jun. 15, 2023

(54) SEMICONDUCTOR MEMORY DEVICE

(71) Applicant: SAMSUNG ELECTRONICS CO., LTD., Suwon-si (KR)

(72) Inventors: Keon Hee PARK, Suwon-si (KR); Soo Ho SHIN, Hwaseong-si (KR); Hyeon-Woo JANG, Hwaseong-si (KR); Dong-Sik PARK, Suwon-si (KR); Ga Eun LEE, Hwaseong-si (KR)

(21) Appl. No.: 17/953,401

(22) Filed: Sep. 27, 2022

(30) Foreign Application Priority Data
Dec. 9, 2021 (KR) 10-2021-0175939

(51) Int. Cl. H01L 27/108

(52) U.S. Cl. CPC H01L 27/10814; H01L 27/10823

(57) ABSTRACT

A semiconductor memory device includes a landing pad on a substrate, a lower electrode on and connected to the landing pad, a dielectric layer on and extending along a profile of the lower electrode, an upper electrode on the dielectric layer, and an upper plate electrode on the upper electrode, the upper plate electrode including a first sub-plate electrode and a second sub-plate electrode doped with boron, a first concentration of the boron in the first sub-plate electrode being greater than a second concentration of the boron in the second sub-plate electrode.

### CROSS-REFERENCE TO RELATED APPLICATION

This application claims priority from Korean Patent Application No. 10-2021-0175939 filed on Dec. 9, 2021, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor memory device and a method of fabricating the same, and more particularly, to a semiconductor memory device having a plurality of wiring lines and node pads intersecting each other, and a method of fabricating the same.

### 2. Description of the Related Art

As semiconductor elements are increasingly highly integrated, individual circuit patterns are becoming more miniaturized in order to implement more semiconductor elements on the same area. That is, as the degree of integration of the semiconductor element increases, a design rule for the components of the semiconductor element is decreasing.

### SUMMARY

According to an aspect of the present disclosure, there is provided a semiconductor memory device including a landing pad on a substrate, a lower electrode connected to the landing pad on the landing pad, a dielectric layer extending along a profile of the lower electrode on the lower electrode, an upper electrode on the dielectric layer, and an upper plate electrode disposed on the upper electrode and including a first sub-plate electrode and a second sub-plate electrode doped with boron (B), wherein a first concentration of the boron in the first sub-plate electrode is greater than a second concentration of the boron in the second sub-plate electrode.

According to another aspect of the present disclosure, there is provided a semiconductor memory device including a landing pad on a substrate, a lower electrode connected to the landing pad on the landing pad, a dielectric layer extending along a profile of the lower electrode on the lower electrode, an upper electrode on the dielectric layer; and an upper plate electrode disposed on the upper electrode and including a silicon plate electrode and a silicon-germanium plate electrode, wherein the silicon plate electrode includes an undoped silicon layer, and the silicon-germanium plate electrode includes a silicon-germanium layer doped with boron having a mass number of 11.

According to still another aspect of the present disclosure there is provided a semiconductor memory device including a substrate including an active area defined by an element separation layer and extending in a first direction, the active area including a first portion and a second portion defined on both sides of the first portion, a word line extending in a second direction different from the first direction and crossing between the first portion of the active area and the second portion of the active area in the substrate and the element separation layer, a bit line contact connected to the first portion of the active area, a bit line, on the bit line contact, connected to the bit line contact and extending in a third direction different from the first direction and the second direction, and a capacitor connected to the second portion of the active area, wherein the capacitor includes, a lower electrode connected to the second portion of the active area, a dielectric layer extending along a profile of the lower electrode on the lower electrode, an upper electrode on the dielectric layer, and an upper plate electrode disposed on the upper electrode and including a silicon plate electrode and a silicon-germanium plate electrode, the silicon-germanium plate electrode includes a first sub-silicon-germanium plate electrode and a second sub-silicon-germanium plate electrode doped with boron (B), and a first concentration of the boron in the first sub-silicon-germanium plate electrode is greater than a second concentration of the boron in the second sub-silicon-germanium plate electrode.

### BRIEF DESCRIPTION OF THE DRAWINGS

Features will become apparent to those of skill in the art by describing in detail exemplary embodiments with reference to the attached drawings, in which:

FIG. 1 is a schematic layout of a semiconductor memory device according to some exemplary embodiments.

FIG. 2 is a layout illustrating only word lines and a cell active area of FIG. 1.

FIG. 3 is an exemplary cross-sectional view taken along line A-A of FIG. 1.

FIG. 4 is an exemplary cross-sectional view taken along line B-B of FIG. 1.

FIG. 5 is an enlarged view of part P of FIG. 3.

FIGS. 6 and 7 are graphs of a concentration of boron doped in an upper plate electrode of FIG. 5, respectively.

FIGS. 8 to 12 are views for describing a semiconductor memory device according to some exemplary embodiments.

FIGS. 13 and 14 are views for describing a semiconductor memory device according to some exemplary embodiments.

FIG. 15 is a cross-sectional view of a semiconductor memory device according to some exemplary embodiments.

FIG. 16 is a cross-sectional view of a semiconductor memory device according to some exemplary embodiments.

FIG. 17 is a cross-sectional view of a semiconductor memory device according to some exemplary embodiments.

FIGS. 18 to 20 are views of a semiconductor memory device according to some exemplary embodiments.

FIG. 21 is a layout view of a semiconductor memory device according to some exemplary embodiments.

FIG. 22 is a perspective view of a semiconductor memory device according to some exemplary embodiments.

FIG. 23 is a cross-sectional view taken along lines C-C and D-D of FIG. 21.

FIG. 24 is a layout view of a semiconductor memory device according to some exemplary embodiments.

FIG. 25 is a perspective view of a semiconductor memory device according to some exemplary embodiments.

### DETAILED DESCRIPTION

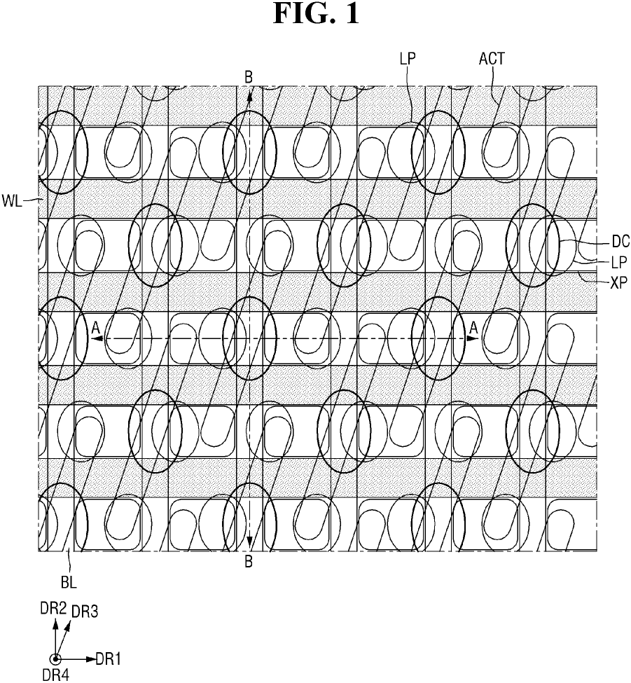

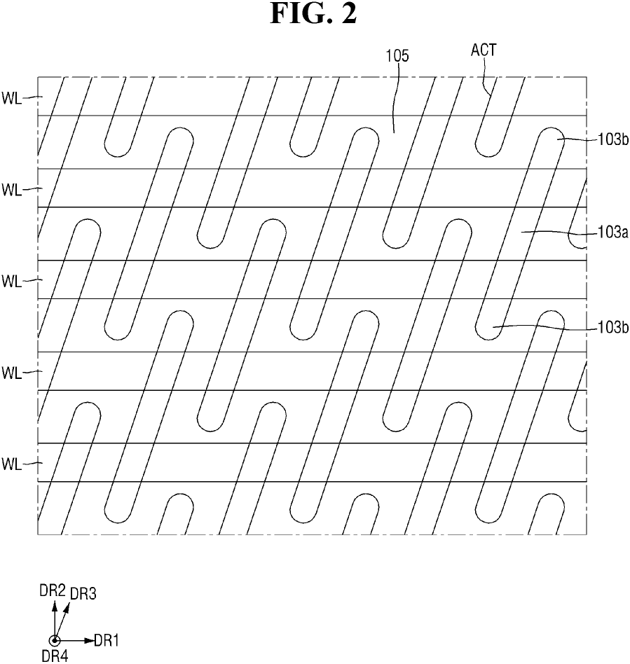

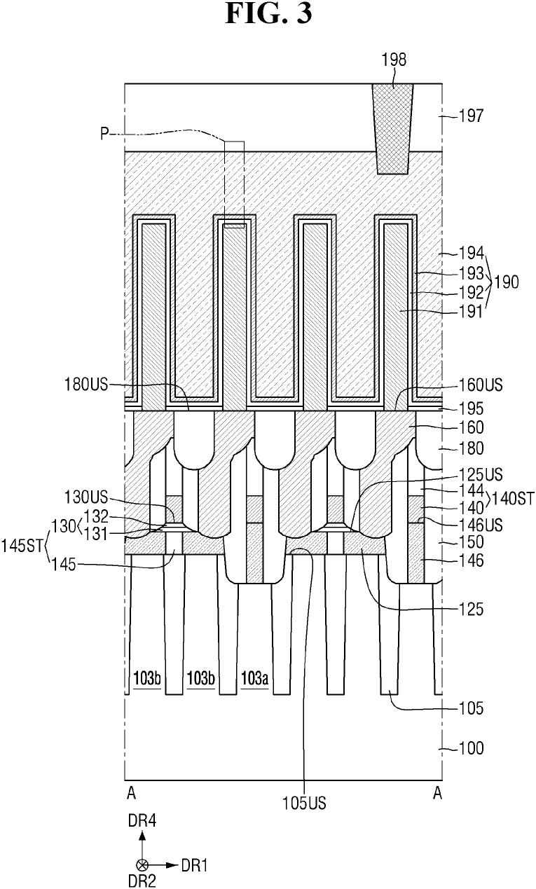

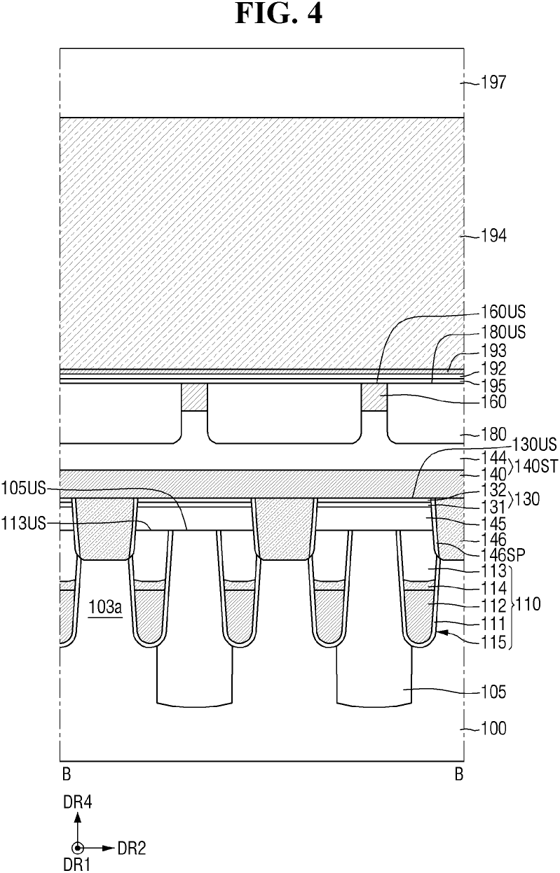

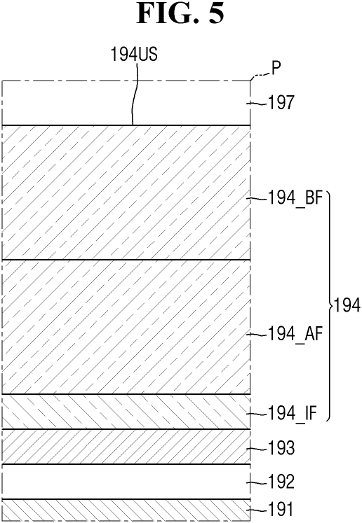

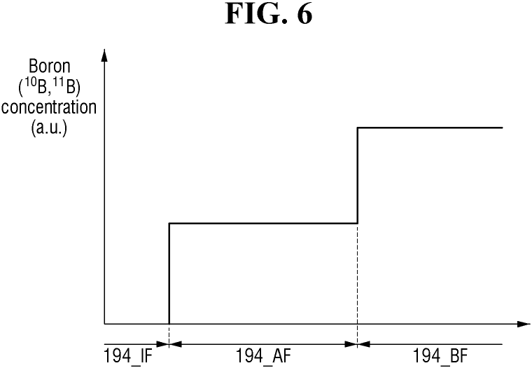

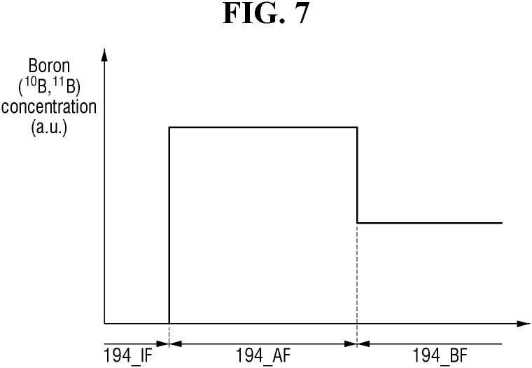

FIG. 1 is a schematic layout of a semiconductor memory device according to some exemplary embodiments. FIG. 2 is a layout illustrating only word lines and cell active areas of FIG. 1. FIG. 3 is an exemplary cross-sectional view taken along line A-A of FIG. 1. FIG. 4 is an exemplary cross-sectional view taken along line B-B of FIG. 1. FIG. 5 is an enlarged view of part P of FIG. 3. FIGS. 6 and 7 are views for explaining a concentration of boron doped in an upper plate electrode of FIG. 5, respectively.

In the drawings of the semiconductor memory device according to some exemplary embodiments, a dynamic random access memory (DRAM) is illustrated, as an example. However, embodiments may be similarly implemented in other memory devices.

Referring to FIGS. 1 and 2, a semiconductor memory device according to some exemplary embodiments may include a plurality of cell active areas ACT. The cell active area ACT may be defined by a cell element separation layer 105 formed in a substrate 100 (in FIG. 3). As a design rule of the semiconductor memory device is reduced, the cell active area ACT may be disposed in a bar shape of a diagonal line or an oblique line as illustrated. For example, the cell active area ACT may extend in a third direction DR3 .

A plurality of gate electrodes crossing the cell active area ACT and extending in a first direction DR1 may be disposed. The plurality of gate electrodes may extend to be parallel to each other. The plurality of gate electrodes may be, e.g., a plurality of word lines WL. The word lines WL may be disposed at equal intervals. A width of the word lines WL or a spacing between the word lines WL may be determined according to a design rule.

Each cell active area ACT may be divided into three portions by two word lines WL extending in the first direction DR1. The cell active area ACT may include a storage connection area 103b and a bit line connection area 103a. The bit line connection area 103a may be located at a central portion of the cell active area ACT, and the storage connection area 103b may be located at an end portion of the cell active area ACT.

For example, the bit line connection area 103a may be an area connected to a bit line BL, and the storage connection area 103b may be an area connected to an information storage portion 190 (in FIG. 3). In other words, the bit line connection area 103a may correspond to a common drain area, and the storage connection area 103b may correspond to a source area. Each word line WL and the bit line connection area 103a and the storage connection area 103b adjacent thereto may constitute a transistor.

A plurality of bit lines BL extending in a second direction DR2 orthogonal to the word line WL may be disposed on the word line WL. The plurality of bit lines BL may extend to be parallel to each other. The bit lines BL may be disposed at equal intervals. A width of the bit lines BL or a spacing between the bit lines BL may be determined according to a design rule.

A fourth direction DR4 may be orthogonal to the first direction DR1, the second direction DR2, and the third direction DR3. The fourth direction DR4 may be a thickness direction of the substrate 100.

The semiconductor memory device according to some exemplary embodiments may include various contact arrangements formed on the cell active area ACT. For example, the various contact arrangements may include a direct contact DC, a node pad XP, and a landing pad LP.

Here, the direct contact DC may refer to a contact that electrically connects the cell active area ACT to the bit line BL. The node pad XP may be a connection pad that connects the cell active area ACT to a lower electrode 191 (in FIG. 3) of a capacitor. Due to an arrangement structure, a contact area between the node pad XP and the cell active area ACT may be small. Accordingly, a conductive landing pad LP may be introduced to expand a contact area with the cell active area ACT and a contact area with the lower electrode 191 (in FIG. 3) of the capacitor.

The landing pad LP may be disposed between the node pad XP and the lower electrode 191 (in FIG. 3) of the capacitor. By expanding the contact area through the introduction of the landing pad LP, contact resistance between the cell active area ACT and the lower electrode 191 of the capacitor may be reduced.

The direct contact DC may be connected to the bit line connection area 103a. The node pad XP may be connected to the storage connection area 103b.

As the node pad XP is disposed at both end portions of the cell active area ACT, the landing pad LP may be disposed adjacent to both ends of the cell active area ACT to at least partially overlap the node pad XP. In other words, the node pad XP may be formed to overlap the cell active area ACT and the cell element separation layer 105 (in FIG. 3) between the adjacent word lines WL and between the adjacent bit lines BL.

The word line WL may be formed in a structure buried in the substrate 100. The word line WL may be disposed across the cell active area ACT between the direct contact DC or the node pad XP. As illustrated, two word lines WL may be disposed to cross one cell active area ACT. As the cell active area ACT extends in the third direction DR3, the word line WL may have an angle of less than 90 degrees with the cell active area ACT.

The direct contact DC and the node pad XP may be symmetrically disposed. Accordingly, the direct contact DC and the node pad XP may be disposed on a straight line in the first direction DR1 and the second direction DR2. Meanwhile, unlike the direct contact DC and the node pad XP, the landing pad LP may be disposed in a zigzag shape in the second direction DR2 in which the bit line BL extends. In addition, the landing pad LP may be disposed to overlap the same side portion of each bit line BL in the first direction DR1 in which the word line WL extends. For example, each of the landing pads LP of a first line may overlap a left side of a corresponding bit line BL, and each of the landing pads LP of a second line may overlap a right side of a corresponding bit line BL.

Referring to FIGS. 1 to 7, the semiconductor memory device according to some exemplary embodiments may include a plurality of cell gate structures 110, a plurality of bit line structures 140ST, a plurality of node connection pads 125, a plurality of bit line contacts 146, and an information storage portion 190.

For example, the substrate 100 may be a silicon substrate or a silicon-on-insulator (SOI). In another example, the substrate 100 may include at least one of silicon germanium, silicon germanium on insulator (SGOI), indium antimonide, lead tellurium compound, indium arsenide, indium phosphide, gallium arsenide, and gallium antimonide.

The cell element separation layer 105 may be formed in the substrate 100. The cell element separation layer 105 may have a shallow trench isolation (STI) structure having excellent element isolation characteristics. The cell element separation layer 105 may define the cell active area ACT in the memory cell area.

The cell active area ACT defined by the cell element separation layer 105 may have a long island shape including a short axis and a long axis as illustrated in FIGS. 1 and 2. The cell active area ACT may have an oblique shape to have an angle of less than 90 degrees with respect to the word line WL formed in the cell element separation layer 105. In addition, the cell active area ACT may have an oblique shape to have an angle of less than 90 degrees with respect to the bit line BL formed on the cell element separation layer 105. For example, the cell element separation layer 105 may include at least one of a silicon oxide layer, a silicon nitride layer, and a silicon oxynitride layer, but is not limited thereto.

The cell element separation layer 105 is illustrated as being formed as a single insulating layer, but it is only for convenience of explanation and the present disclosure is not limited thereto. For example, the cell element separation layer 105 may be formed as a single insulating layer or a plurality of insulating layers according to a distance between the adjacent cell active areas ACT. An upper surface 105US of the cell element separation layer and an upper surface of the substrate 100 are illustrated as being on the same plane, but this is only for convenience of explanation and the present disclosure is not limited thereto.

The cell gate structure 110 may be formed in the substrate 100 and the cell element separation layer 105. The cell gate structure 110 may be formed across the cell element separation layer 105 and the cell active area ACT defined by the cell element separation layer 105.

The cell gate structure 110 may include a cell gate trench 115, a cell gate insulating layer 111, a cell gate electrode 112, a cell gate capping pattern 113, and a cell gate capping conductive layer 114. Here, the cell gate electrode 112 may correspond to the word line WL. For example, the cell gate electrode 112 may be the word line WL of FIG. 1. In another example, unlike the drawing, the cell gate structure 110 may not include the cell gate capping conductive layer 114.

In detail, the cell gate trench 115 may be relatively deep in the cell element separation layer 105 and relatively shallow in the cell active areas ACT. A bottom surface of the word line WL may be curved. That is, a depth of the cell gate trench 115 in the cell element separation layer 105 may be greater than a depth of the cell gate trench 115 in the cell active region ACT.

The cell gate insulating layer 111 may extend, e.g., conformally, along a sidewall and a bottom surface of the cell gate trench 115. The cell gate insulating layer 111 may extend along a profile of at least a portion of the cell gate trench 115.

The cell gate insulating layer 111 may include, e.g., at least one of silicon oxide, silicon nitride, silicon oxynitride, or a high-k material having a higher dielectric constant than the silicon oxide. The high-k material may include, e.g., at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The cell gate electrode 112 may be disposed on the cell gate insulating layer 111. The cell gate electrode 112 may fill a portion of the cell gate trench 115. The cell gate capping conductive layer 114 may extend along an upper surface of the cell gate electrode 112.

The cell gate electrode 112 may include at least one of, e.g., a metal, a metal alloy, a conductive metal nitride, a conductive metal carbonitride, a conductive metal carbide, a conductive metal silicide, a doped semiconductor material, a conductive metal oxynitride, and a conductive metal oxide. The cell gate electrode 112 may include, e.g., at least one of TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrO, RuO, and combinations thereof.

The cell gate capping conductive layer 114 may include, e.g., one of polysilicon, polysilicon-germanium, amorphous silicon, and amorphous silicon-germanium, but is not limited thereto.

The cell gate capping pattern 113 may be disposed on the cell gate electrode 112 and the cell gate capping conductive layer 114. The cell gate capping pattern 113 may fill the cell gate trench 115 remaining after the cell gate electrode 112 and the cell gate capping conductive layer 114 are formed. For example, the cell gate insulating layer 111 may extend along sidewalls of the cell gate capping pattern 113.

The cell gate capping pattern 113 may include, e.g., at least one of silicon nitride (SiN), silicon oxynitride (SiON), silicon oxide (SiO₂), silicon carbonitride (SiCN), silicon oxycarbonitride (SiOCN), and combinations thereof. For example, an upper surface 113US of the cell gate capping pattern 113 may be on the same plane as the upper surface 105US of the cell element separation layer.

For example, an impurity doped area may be formed on at least one side of the cell gate structure 110. The impurity doped area may be a source/drain area of the transistor. The impurity doped area may be formed in the storage connection area 103b and the bit line connection area 103a of FIG. 2.

In FIG. 2, when the transistor including each word line WL and the bit line connection area 103a and the storage connection area 103b adjacent thereto is an NMOS, the storage connection area 103b and the bit line connection area 103a may include doped n-type impurities, e.g., at least one of phosphorus (P), arsenic (As), antimony (Sb), and bismuth (Bi). When the transistor including each word line WL and the bit line connection area 103a and the storage connection area 103b adjacent thereto is a PMOS, the storage connection area 103b and the bit line connection area 103a may include doped p-type impurities, e.g., boron (B).

The bit line structure 140ST may include a cell conductive line 140 and a cell line capping layer 144. The cell conductive line 140 may be disposed on the substrate 100 and the cell element separation layer 105, in which the cell gate structure 110 is formed. The cell conductive line 140 may intersect the cell element separation layer 105 and the cell active area ACT defined by the cell element separation layer 105. The cell conductive line 140 may be formed to intersect the cell gate structure 110. Here, the cell conductive line 140 may correspond to the bit line BL. For example, the cell conductive line 140 may be the bit line BL of FIG. 1.

The cell conductive line 140 may include, e.g., at least one of a semiconductor material doped with impurities, a conductive metal silicide, a conductive metal nitride, a conductive metal oxide, a two-dimensional (2D) material, a metal, and a metal alloy. In the semiconductor memory device according to some exemplary embodiments, the 2D material may be a metallic material and/or a semiconductor material. The 2D material may include a two-dimensional allotrope or a two-dimensional compound, and may include, e.g., at least one of graphene, molybdenum disulfide (MoS₂), molybdenum diselenide (MoSe₂), tungsten diselenide (WSe₂), and tungsten disulfide (WS₂).

For example, as illustrated in FIGS. 3-4, the cell conductive line 140 may be a single layer. In another example, the cell conductive line 140 may include a plurality of conductive layers on which conductive materials are stacked.

The cell line capping layer 144 may be disposed on the cell conductive line 140. The cell line capping layer 144 may extend in the second direction DR2 along the upper surface of the cell conductive line 140. The cell line capping layer 144 may include, e.g., at least one of a silicon nitride layer, a silicon oxynitride, a silicon carbonitride, and a silicon oxycarbonitride.

In the semiconductor memory device according to some exemplary embodiments, the cell line capping layer 144 may include a silicon nitride layer. The cell line capping layer 144 may be a single layer or a multi-layer.

The bit line contact 146 may be formed between the cell conductive line 140 and the substrate 100. The cell conductive line 140 may be disposed on the bit line contact 146. The bit line contact 146 may be formed between the bit line connection area 103a of the cell active area ACT and the cell conductive line 140. The bit line contact 146 may be connected to the bit line connection area 103a.

In a plan view, the bit line contact 146 may have a circular or elliptical shape. A planar area of the bit line contact 146 may be greater than an overlapping area of the bit line connection area 103a and one cell conductive line 140. The planar area of the bit line contact 146 may be larger than that of one bit line connection area 103a.

The bit line contact 146 may include an upper surface 146US connected to the cell conductive line 140. A width of the bit line contact 146 in the first direction DR1 may be constant as a distance from the upper surface 146US of the bit line contact increases, but the present disclosure is not limited thereto, e.g., the width of the bit line contact 146 in the first direction DR1 may increase as a distance from the upper surface 146US of the bit line contact increases.

The bit line contact 146 may be formed between the cell conductive line 140 and the substrate 100. Here, the bit line contact 146 may correspond to the direct contact DC. The bit line contact 146 may include, e.g., at least one of a semiconductor material doped with impurities, a conductive metal silicide, a conductive metal nitride, a conductive metal oxide, a metal, and a metal alloy.

The node connection pad 125 may be disposed on the substrate 100. The node connection pad 125 may be disposed on the storage connection area 103b of the cell active area ACT. The node connection pad 125 may be connected to the storage connection area 103b.

The node connection pad 125 may be disposed between cell conductive lines 140 adjacent to each other in the first direction DR1. The node connection pad 125 may be disposed between the cell gate electrodes 112 adjacent to each other in the second direction DR2.

Based on the upper surface 105US of the cell element separation layer 105, an upper surface 125US of the node connection pad 125 is lower than the upper surface 146US of the bit line contact 146. Based on the upper surface 105US of the cell element separation layer 105, the upper surface 125US of the node connection pad 125 is lower than the bottom surface of the cell conductive line 140.

The node connection pad 125 may electrically connect the information storage portion 190 and the substrate 100. Here, the node connection pad 125 may correspond to the node pad XP. The node connection pad 125 may include, e.g., at least one of a semiconductor material doped with impurities, a conductive metal silicide, a conductive metal nitride, a conductive metal oxide, a metal, and a metal alloy.

A pad separation structure 145ST may separate the node connection pads 125 adjacent in the first direction DR1. The pad separation structure 145ST may also separate the node connection pads 125 adjacent in the second direction DR2. The pad separation structure 145ST covers the upper surface 125US of the node connection pad.

The pad separation structure 145ST may include a pad separation pattern 145 and an upper cell insulating layer 130. The upper cell insulating layer 130 may be disposed on the pad separation pattern 145.

When the node connection pad 125 includes a first node connection pad and a second node connection pad spaced apart from each other in the first direction DR1, the pad separation pattern 145 may separate the first node connection pad and the second node connection pad in the first direction DR1. The pad separation pattern 145 may also separate the node connection pads 125 adjacent in the second direction DR2.

The upper cell insulating layer 130 covers the upper surface 125US of the node connection pad. When the node connection pad 125 includes the first node connection pad and the second node connection pad spaced apart from each other in the first direction DR1, the upper cell insulating layer 130 may cover an upper surface of the first node connection pad and an upper surface of the second node connection pad.

An upper surface 130US of the upper cell insulating layer may be on the same plane as the upper surface 146US of the bit line contact. That is, a height of the upper surface 130US of the upper cell insulating layer may be the same as a height of the upper surface 146US of the bit line contact with respect to the upper surface 105US of the cell element separation layer.

The pad separation pattern 145 and the upper cell insulating layer 130 may be disposed between the bit line contacts 146 adjacent in the second direction DR2. The cell conductive line 140 may be disposed on the upper surface of the pad separation structure 145ST. The cell conductive line 140 may be disposed on the upper surface 130US of the upper cell insulating layer. The upper surface of the pad separation structure 145ST may be the upper surface 130US of the upper cell insulating layer. The upper surface of the pad separation structure 145ST may be on the same plane as a bottom surface of the cell conductive line 140.

In FIG. 4, a bit line contact spacer 146SP may be disposed between the bit line contact 146 and the pad separation pattern 145. The bit line contact spacer 146SP may be disposed along the sidewalls of the bit line contact 146. The bit line contact spacers 146SP disposed on the sidewalls of the bit line contact 146 are spaced apart from each other in the second direction DR2.

The bit line contact spacer 146SP may include, e.g., at least one of silicon nitride (SiN), silicon oxynitride (SiON), and silicon oxide (SiO₂). The bit line contact spacer 146SP may be a single layer or a multi-layer.

The pad separation pattern 145 may include, e.g., at least one of silicon nitride (SiN), silicon oxynitride (SiON), silicon oxide (SiO₂), silicon carbonitride (SiCN), silicon oxycarbonitride (SiOCN), and combinations thereof. For example, the upper cell insulating layer 130 may be a single layer. In another example, as illustrated in FIG. 3, the upper cell insulating layer 130 may be a multilayer including a first upper cell insulating layer 131 and a second upper cell insulating layer 132. For example, the first upper cell insulating layer 131 may include a silicon oxide layer, and the second upper cell insulating layer 132 may include a silicon nitride layer. A width of the upper cell insulating layer 130 in the first direction DR1 is illustrated as decreasing as a distance from the substrate 100 increases, but is not limited thereto.

A bit line spacer 150 may be disposed on sidewalls of the cell conductive line 140 and the cell line capping layer 144. In the portion of the cell conductive line 140 where the bit line contact 146 is formed, the bit line spacer 150 may be disposed on the sidewalls of the cell conductive line 140, the cell line capping layer 144, and the bit line contact 146. In the remaining portion of the cell conductive line 140 where the bit line contact 146 is not formed, the bit line spacer 150 may be disposed on the upper cell insulating layer 130.

The bit line spacer 150 may be a single layer or have a multilayer structure. The bit line spacer 150 may include, e.g., one of a silicon oxide layer, a silicon nitride layer, a silicon oxynitride layer (SiON), a silicon oxycarbonitride layer (SiOCN), air, and a combination thereof.

A storage pad 160 may be disposed on each node connection pad 125. The storage pad 160 may be electrically connected to the node connection pad 125. The storage pad 160 may be connected to the storage connection area 103b of the cell active area ACT. Here, the storage pad 160 may correspond to the landing pad LP.

In the semiconductor memory device according to some exemplary embodiments, the storage pad 160 may extend to the node connection pad 125 to be connected to the node connection pad 125. The storage pad 160 may overlap a portion of the upper surface of the bit line structure 140ST. The storage pad 160 may include, e.g., at least one of a semiconductor material doped with impurities, a conductive metal silicide, a conductive metal nitride, a conductive metal carbide, a conductive metal oxide, a metal, and a metal alloy.

A pad separation insulating layer 180 may be formed on the storage pad 160 and the bit line structure 140ST. For example, the pad separation insulating layer 180 may be disposed on the cell line capping layer 144. The pad separation insulating layer 180 may define the storage pad 160 forming a plurality of isolation areas.

The pad separation insulating layer 180 does not cover an upper surface 160US of the storage pad. The pad separation insulating layer 180 may fill a pad separation recess. The pad separation recess may separate the storage pads 160 adjacent to each other. For example, the upper surface 160US of the storage pad may be on the same plane as an upper surface 180US of the pad separation insulating layer.

The pad separation insulating layer 180 may include an insulating material and may electrically separate the plurality of storage pads 160 from each other. For example, the pad separation insulating layer 180 may include, e.g., at least one of a silicon oxide layer, a silicon nitride layer, a silicon oxynitride layer, a silicon oxycarbonitride layer, and a silicon carbonitride layer.

A first etching stop layer 195 may be disposed on the storage pad 160 and the pad separation insulating layer 180. The first etching stop layer 195 may include, e.g., at least one of a silicon nitride layer, a silicon carbonitride layer, a silicon boron nitride layer (SiBN), a silicon oxynitride layer, and a silicon oxycarbide layer.

An information storage portion 190 may be disposed on the storage pad 160. The information storage portion 190 may be electrically connected to the storage pad 160. A portion of the information storage portion 190 may be disposed in the first etching stop layer 195.

The information storage portion 190 may include, e.g., a capacitor. The information storage portion 190 may include a lower electrode 191, a capacitor dielectric layer 192, an upper electrode 193, and an upper plate electrode 194.

The lower electrode 191 may be disposed on the storage pad 160. For example, as illustrated in FIG. 3, the lower electrode 191 may have a pillar shape. In another example, the lower electrode 191 may also have a cylindrical shape. The lower electrode 191 may include, e.g., a conductive metal nitride (e.g., a titanium nitride, a tantalum nitride, a niobium nitride, a tungsten nitride, or the like), a metal (e.g., ruthenium, iridium, titanium, tantalum, or the like), a conductive metal oxide (e.g., an iridium oxide, a niobium oxide, or the like), and the like.

The capacitor dielectric layer 192 may be formed on the lower electrode 191. The capacitor dielectric layer 192 may be formed along a profile of the lower electrode 191. The capacitor dielectric layer 192 may extend along an upper surface of the first etching stop layer 195.

The capacitor dielectric layer 192 may include, e.g., at least one of silicon oxide, silicon nitride, silicon oxynitride, a high-k material, and combinations thereof. In the semiconductor memory device according to some exemplary embodiments, the capacitor dielectric layer 192 may include a stacked layer structure in which zirconium oxide, aluminum oxide, and zirconium oxide are sequentially stacked. In the semiconductor memory device according to some exemplary embodiments, the capacitor dielectric layer 192 may include a dielectric layer including hafnium (Hf). In the semiconductor memory device according to some exemplary embodiments, the capacitor dielectric layer 192 may have a stacked layer structure of a ferroelectric material layer and a paraelectric material layer.

The upper electrode 193 may be formed on the capacitor dielectric layer 192. The upper electrode 193 may extend along a profile of the capacitor dielectric layer 192.

The upper electrode 193 may include, e.g., a conductive metal nitride (e.g., a titanium nitride, a tantalum nitride, a niobium nitride, a tungsten nitride, or the like), a metal (e.g., ruthenium, iridium, titanium, tantalum, or the like), a conductive metal oxide (e.g., an iridium oxide, a niobium oxide, or the like), and the like.

The upper plate electrode 194 may be disposed on the upper electrode 193. The upper plate electrode 194 covers an outer sidewall of the lower electrode 191. As illustrated in FIG. 5, the upper plate electrode 194 may include a boundary plate electrode 194_IF, a first sub-plate electrode 194_AF, and a second sub-plate electrode 194_BF.

The boundary plate electrode 194_IF may be disposed on the upper electrode 193. The boundary plate electrode 194_IF may extend along the profile of the upper electrode 193. The boundary plate electrode 194_IF may be disposed between the upper electrode 193 and the first sub-plate electrode 194_AF.

The boundary plate electrode 194_IF may include an undoped semiconductor material layer. Here, the “undoped semiconductor material layer” refers to a semiconductor material layer that does not include intentionally implanted or doped impurities. That is, when the semiconductor material layer is formed, p-type impurities, n-type impurities, or other impurities are not intentionally introduced into the semiconductor material layer. However, the undoped semiconductor material layer may include impurities that have diffused from an adjacent layer.

The boundary plate electrode 194_IF may include, e.g., an undoped silicon layer. The boundary plate electrode 194_IF may be a silicon plate electrode.

The first sub-plate electrode 194_AF and the second sub-plate electrode 194_BF may be sequentially disposed on the boundary plate electrode 194_IF. The first sub-plate electrode 194_AF may be disposed between the boundary plate electrode 194_IF and the second sub-plate electrode 194_BF.

Each of the first sub-plate electrode 194_AF and the second sub-plate electrode 194_BF may include a semiconductor material layer doped with boron (B). For example, each of the first sub-plate electrode 194_AF and the second sub-plate electrode 194_BF may include a silicon-germanium layer doped with boron.

The first sub-plate electrode 194_AF and the second sub-plate electrode 194_BF may be silicon-germanium plate electrodes. The first sub-plate electrode 194_AF may be a first sub-silicon-germanium plate electrode, and the second sub-plate electrode 194_BF may be a second sub-silicon-germanium plate electrode.

The boron doped into the first sub-plate electrode 194_AF and the second sub-plate electrode 194_BF may include a first boron and a second boron. The first boron may be a boron atom having a mass number of 11. The second boron may be a boron atom having a mass number of 10. The first sub-plate electrode 194_AF and the second sub-plate electrode 194_BF may include the first boron having the mass number of 11 and the second boron having the mass number of 10, respectively.

For example, a first concentration (/cm³) of boron in the first sub-plate electrode 194_AF may be different from a second concentration (/cm³) of boron in the second sub-plate electrode 194_BF. This will be described in more detail below with reference to FIGS. 6 and 7.

For example, in FIGS. 6 and 7, the concentration of boron is illustrated as being changed in a step shape at a boundary between the first sub-plate electrode 194_AF and the second sub-plate electrode 194_BF, but this is only for convenience of explanation and the present disclosure is not limited thereto. In another example, at the boundary between the first sub-plate electrode 194_AF and the second sub-plate electrode 194_BF, the concentration of boron may be gradually changed.

For example, the upper plate electrode 194 may include a pair of first sub-plate electrodes 194_AF and second sub-plate electrodes 194_BF. In another example, the upper plate electrode 194 may include a plurality of first sub-plate electrodes 194_AF and a plurality of second sub-plate electrodes 194_BF that are alternately stacked.

For example, the number of first sub-plate electrodes 194_AF included in the upper plate electrode 194 may be the same as the number of second sub-plate electrodes 194_BF included in the upper plate electrode 194. An upper surface 194US of the upper plate electrode may be included in the second sub-plate electrode 194_BF.

For example, referring to FIG. 6, the first concentration of boron in the first sub-plate electrode 194_AF may be smaller than the second concentration of boron in the second sub-plate electrode 194_BF. As the second sub-plate electrode 194_BF doped with a high concentration of boron is disposed at the outermost portion of the upper plate electrode 194, defects of the upper plate electrode 194 due to wet etching may be prevented in a process of fabricating the semiconductor memory device.

In another example, referring to FIG. 7, the first concentration of boron in the first sub-plate electrode 194_AF may be greater than the second concentration of boron in the second sub-plate electrode 194_BF. As the first sub-plate electrode 194_AF doped with a high concentration of boron is disposed adjacent to the upper electrode 193, resistance between the upper plate electrode 194 and the upper electrode 193 may be reduced.

Referring back to FIGS. 3-5, an interlayer insulating layer 197 may be disposed on the upper plate electrode 194. The interlayer insulating layer 197 may cover the upper surface 194US of the upper plate electrode.

The interlayer insulating layer 197 may include, e.g., at least one of silicon oxide, silicon nitride, silicon oxynitride, and a low-k material. The low-k material may include, e.g., Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoSiloxane (DADBS), TriMethylSilyl Phosphate (TMSP), PolyTetraFluoroEthylene (PTFE), Tonen SilaZen (TOSZ), Fluoride Silicate Glass (FSG), polyimide nanofoams, e.g., polypropylene oxide, Carbon Doped silicon Oxide (CDO), Organo Silicate Glass (OSG), SiLK, Amorphous Fluorinated Carbon, silica aerogels, silica xerogels, mesoporous silica, or a combination thereof, but is not limited thereto.

As illustrated in FIG. 3, a contact plug 198 may be disposed in the interlayer insulating layer 197. The contact plug 198 may be electrically connected to the upper plate electrode 194. A portion of the contact plug 198 may be recessed into the upper plate electrode 194.

The contact plug 198 may include, e.g., at least one of a metal, a metal alloy, a metal nitride, a metal carbide, a metal carbonitride, a conductive metal silicide, a metal oxide, and a semiconductor material doped with impurities. The contact plug 198 may be a single layer or a multi-layer.

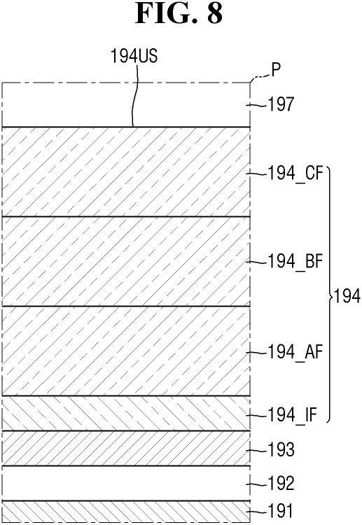

FIGS. 8 to 12 are views of a semiconductor memory device according to some exemplary embodiments. For convenience of explanation, only points different from those described with reference to FIGS. 1 to 7 will be mainly described.

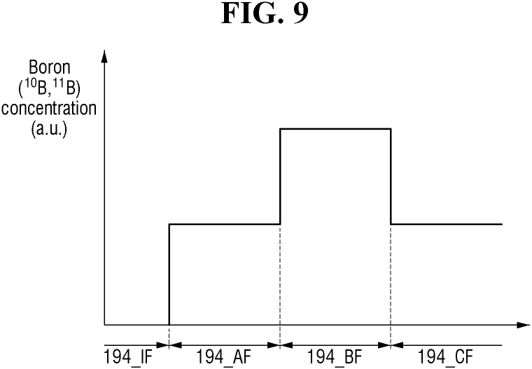

For reference, FIG. 8 is an enlarged view of part P of FIG. 3. FIGS. 9 to 12 are graphs of a concentration of boron doped in the upper plate electrode 194 of FIG. 8, respectively.

Referring to FIGS. 8 to 12, in the semiconductor memory device according to some exemplary embodiments, the upper plate electrode 194 may further include a third sub-plate electrode 194_CF on the second sub-plate electrode 194_BF. The second sub-plate electrode 194_BF may be disposed between the first sub-plate electrode 194_AF and the third sub-plate electrode 194_CF.

The third sub-plate electrode 194_CF may include a semiconductor material layer doped with boron (B). For example, the third sub-plate electrode 194_CF may include a silicon-germanium layer doped with boron. The third sub-plate electrode 194_CF may be a third sub-silicon-germanium plate electrode. The third sub-plate electrode 194_CF may include the first boron having a mass number of 11 and a second boron having a mass number of 10.

For example, a first concentration (/cm³) of boron in the first sub-plate electrode 194_AF may be different from a second concentration (/cm³) of boron in the second sub-plate electrode 194_BF. The second concentration (/cm³) of boron in the second sub-plate electrode 194_BF may be different from a third concentration (/cm³) of boron in the third sub-plate electrode 194_CF.

In FIG. 9, the first concentration of boron in the first sub-plate electrode 194_AF may be smaller than the second concentration of boron in the second sub-plate electrode 194_BF. The third concentration of boron in the third sub-plate electrode 194_CF may be smaller than the second concentration of boron in the second sub-plate electrode 194_BF. As the second sub-plate electrode 194_BF doped with a high concentration of boron is disposed near a center of the upper plate electrode 194, resistance between the contact plug 198 (in FIG. 3) and the upper plate electrode 194 may be reduced.

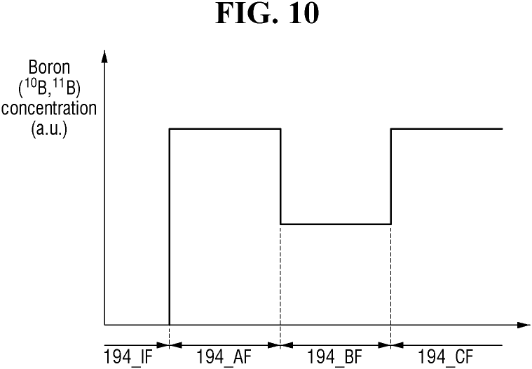

In FIG. 10, the first concentration of boron in the first sub-plate electrode 194_AF may be greater than the second concentration of boron in the second sub-plate electrode 194_BF. The third concentration of boron in the third sub-plate electrode 194_CF may be greater than the second concentration of boron in the second sub-plate electrode 194_BF.

As the third sub-plate electrode 194_CF doped with a high concentration of boron is disposed at the outermost portion of the upper plate electrode 194, defects of the upper plate electrode 194 due to wet etching may be prevented in a process of fabricating the semiconductor memory device. In addition, as the first sub-plate electrode 194_AF doped with a high concentration of boron is disposed adjacent to the upper electrode 193, resistance between the upper plate electrode 194 and the upper electrode 193 may be reduced.

For example, in FIGS. 9 and 10, the first concentration of boron in the first sub-plate electrode 194_AF is the same as the third concentration of boron in the third sub-plate electrode 194_CF. In another example, the first concentration of boron in the first sub-plate electrode 194_AF may be different from the third concentration of boron in the third sub-plate electrode 194_CF.

For example, the upper plate electrode 194 may include a three-layered sub-plate electrode as illustrated in FIGS. 9 and 10. The upper surface 194US of the upper plate electrode may be included in the third sub-plate electrode 194_CF.

In another example, in the upper plate electrode 194, a plurality of high-concentration sub-plate electrodes doped with a high concentration of boron and a plurality of low-concentration sub-plate electrodes doped with a low concentration of boron may be alternately stacked. In this case, a difference between the number of high concentration sub-plate electrodes and the number of low concentration sub-plate electrodes may be one.

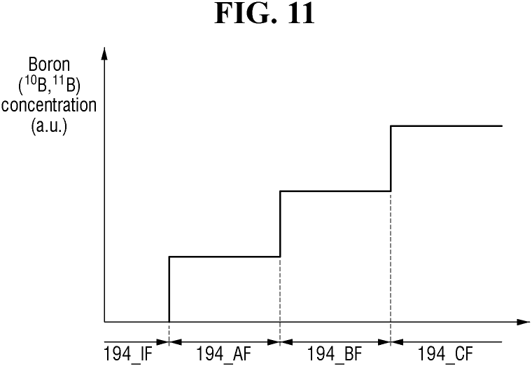

In FIG. 11, the first concentration of boron in the first sub-plate electrode 194_AF may be smaller than the second concentration of boron in the second sub-plate electrode 194_BF. The third concentration of boron in the third sub-plate electrode 194_CF may be greater than the second concentration of boron in the second sub-plate electrode 194_BF.

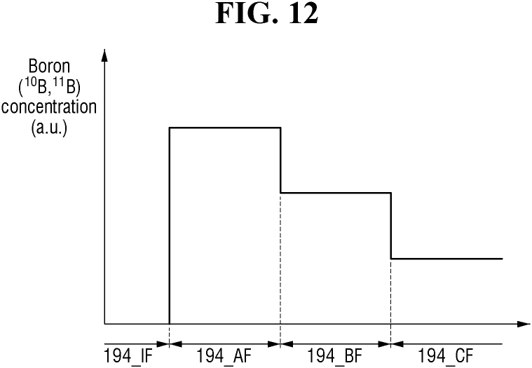

In FIG. 12, the first concentration of boron in the first sub-plate electrode 194_AF may be greater than the second concentration of boron in the second sub-plate electrode 194_BF. The third concentration of boron in the third sub-plate electrode 194_CF may be smaller than the second concentration of boron in the second sub-plate electrode 194_BF.

The upper plate electrode 194 may include a three-layered sub-plate electrode in which the concentration of boron sequentially increases or decreases as illustrated in FIGS. 11 and 12.

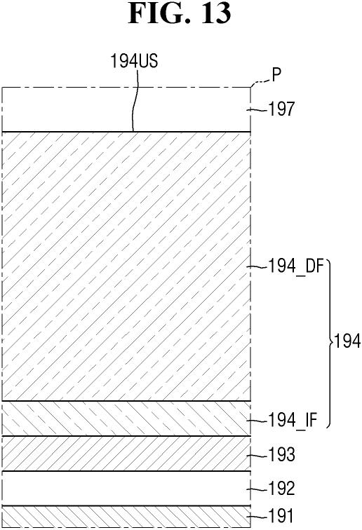

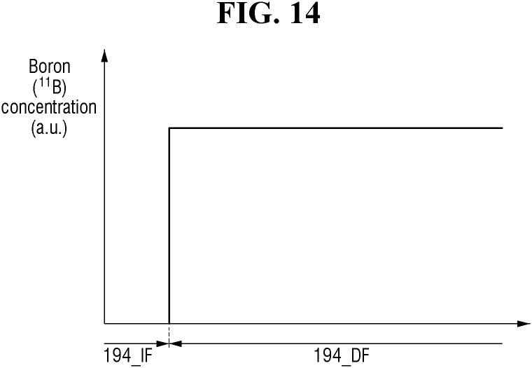

FIGS. 13 and 14 are views for describing a semiconductor memory device according to some exemplary embodiments. For convenience of explanation, only points different from those described with reference to FIGS. 1 to 7 will be mainly described.

For reference, FIG. 13 is an enlarged view of part P of FIG. 3. FIG. 14 is a graph of a concentration of boron doped in the upper plate electrode 194 of FIG. 13.

Referring to FIGS. 13 and 14, in the semiconductor memory device according to some exemplary embodiments, the upper plate electrode 194 may include a fourth sub-plate electrode 194_DF doped with the first boron having a mass number of 11. That is, the upper plate electrode 194 may include a single electrode layer, i.e., the fourth sub-plate electrode 194_DF doped with the first boron having a mass number of 11, on boundary plate electrode 194_IF.

The fourth sub-plate electrode 194_DF does not include a second boron having a mass number of 10. That is, the second boron having the mass number of 10 is not doped into the fourth sub-plate electrode 194_DF.

The fourth sub-plate electrode 194_DF may include a semiconductor material layer doped with the first boron having a mass number of 11. The fourth sub-plate electrode 194_DF may include a silicon-germanium layer doped with the first boron having a mass number of 11. The fourth sub-plate electrode 194_DF may be a fourth sub-silicon-germanium plate electrode. For example, the upper plate electrode 194 may not include the silicon-germanium layer doped with the second boron having a mass number of 10.

The boundary plate electrode 194_IF may be disposed, e.g., directly, between the upper electrode 193 and the fourth sub-plate electrode 194_DF. The upper surface 194US of the upper plate electrode may be included in the fourth sub-plate electrode 194_DF.

The second boron having a mass number of 10 doped into the semiconductor material layer may undergo nuclear fission by thermal neutrons. Due to the nuclear fission of the second boron having a mass number of 10, the performance and reliability of the semiconductor memory device may deteriorate.

However, as only the first boron having a mass number of 11 is doped into the fourth sub-plate electrode 194_DF, the nuclear fission of boron in the upper plate electrode 194 may not occur. Through this, the performance and reliability of the semiconductor memory device may be improved.

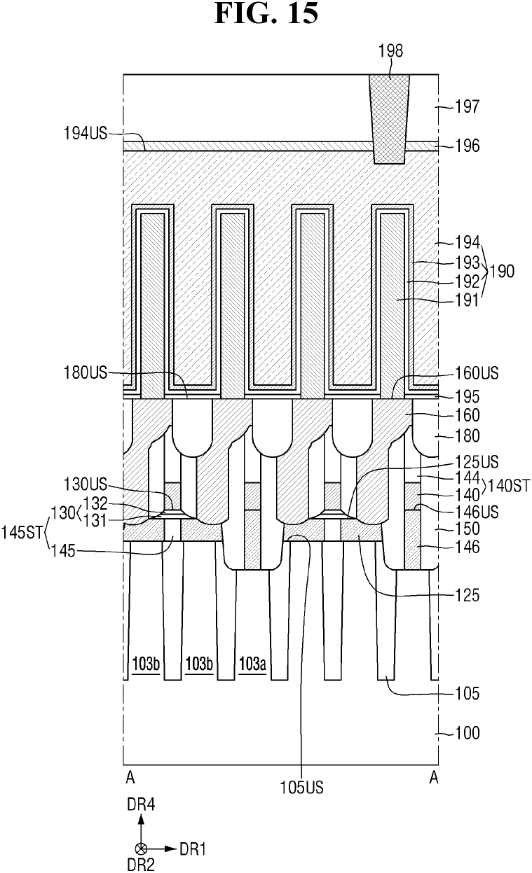

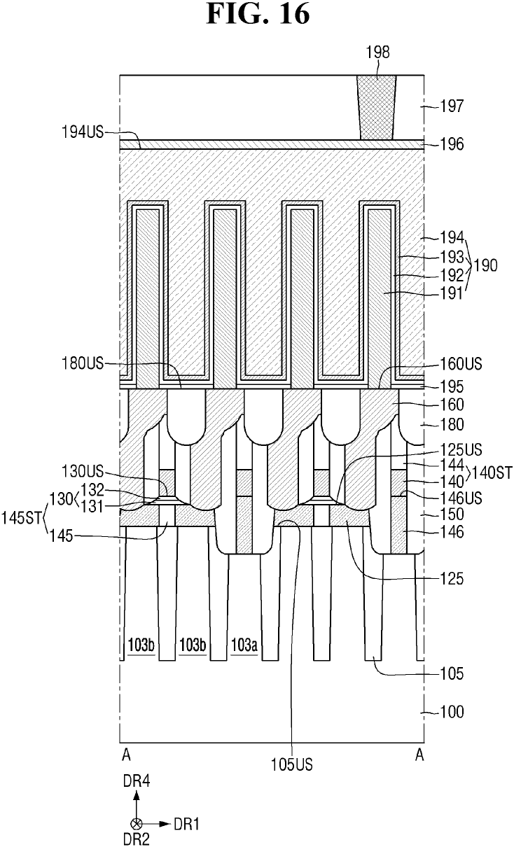

FIG. 15 is a cross-sectional view of a semiconductor memory device according to some exemplary embodiments. FIG. 16 is a cross-sectional view of a semiconductor memory device according to some exemplary embodiments. For convenience of explanation, only points different from those described with reference to FIGS. 1 to 14 will be mainly described.

Referring to FIGS. 15 and 16, a semiconductor memory device according to some exemplary embodiments may further include a capping metal electrode 196 disposed on the upper plate electrode 194. The upper plate electrode 194 may be disposed between the capping metal electrode 196 and the upper electrode 193.

The capping metal electrode 196 extends along the upper surface 194US of the upper plate electrode. The capping metal electrode 196 may include at least one of a metal, a metal alloy, a conductive metal nitride, a conductive metal carbonitride, a conductive metal carbide, a conductive metal oxynitride, and a conductive metal oxide.

In FIG. 15, the contact plug 198 may penetrate through the capping metal electrode 196. The contact plug 198 may be connected to the upper plate electrode 194. A portion of the contact plug 198 may be recessed into the upper plate electrode 194.

In FIG. 16, the contact plug 198 does not penetrate through the capping metal electrode 196. The contact plug 198 may be disposed on the capping metal electrode 196. The contact plug 198 may be in contact with the capping metal electrode 196. The contact plug 198 may be connected to the upper plate electrode 194 through the capping metal electrode 196.

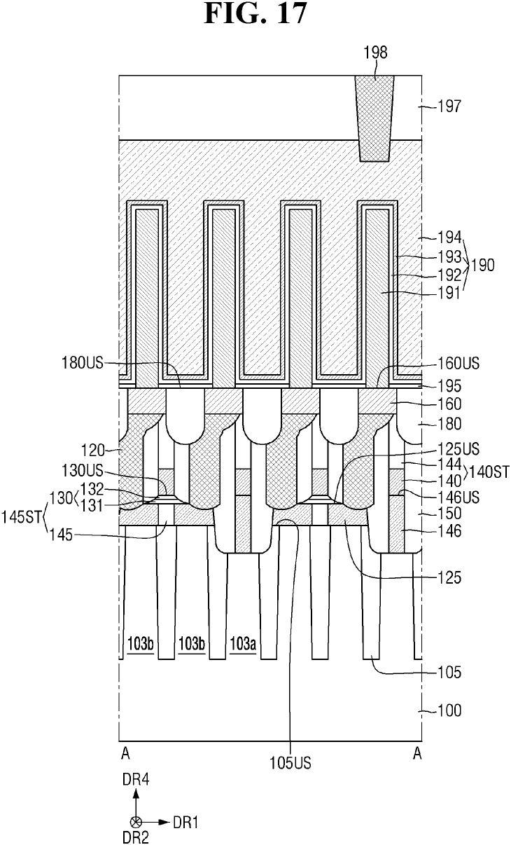

FIG. 17 is a cross-sectional view of a semiconductor memory device according to some exemplary embodiments. For convenience of explanation, only points different from those described with reference to FIGS. 1 to 14 will be mainly described.

Referring to FIG. 17, the semiconductor memory device according to some exemplary embodiments may further include a storage contact 120 disposed between the node connection pad 125 and the storage pad 160. The storage contact 120 may connect the node connection pad 125 and the storage pad 160. The storage contact 120 may include, e.g., at least one of a semiconductor material doped with impurities, a conductive metal silicide, a conductive metal nitride, a conductive metal oxide, a metal, and a metal alloy.

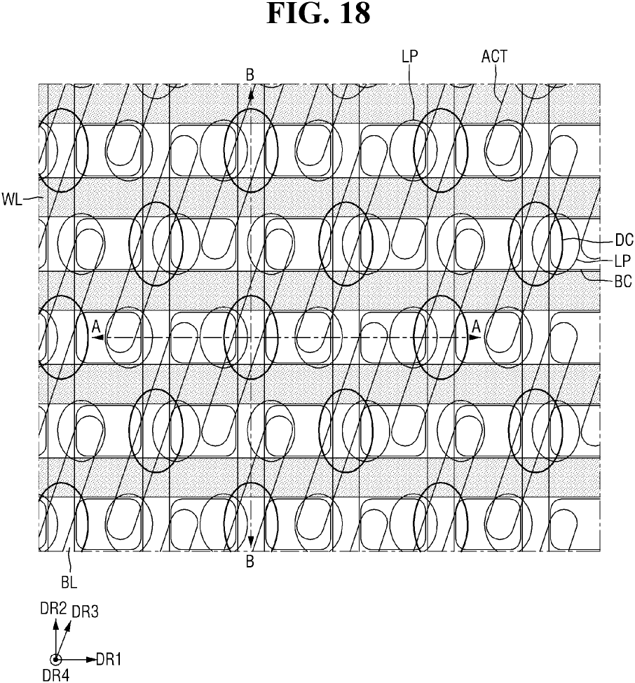

FIGS. 18 to 20 are views of a semiconductor memory device according to some exemplary embodiments. For convenience of explanation, only points different from those described with reference to FIGS. 1 to 7 will be mainly described.

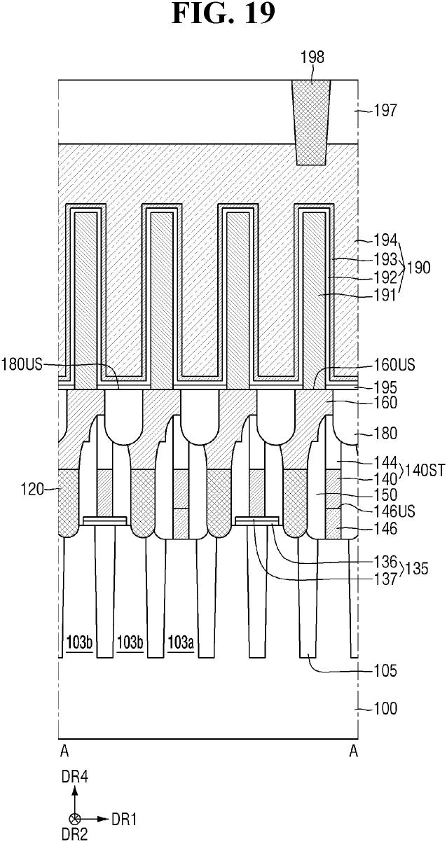

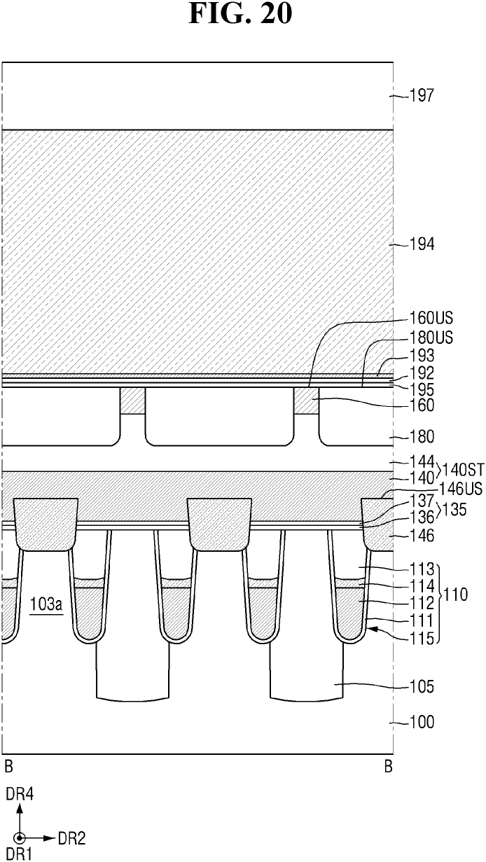

For reference, FIG. 18 is a schematic layout of a semiconductor memory device according to some exemplary embodiments. FIGS. 19 and 20 are cross-sectional views taken along lines A-A and B-B of FIG. 18, respectively.

Referring to FIGS. 18 to 20, a semiconductor memory device according to some exemplary embodiments may include a buried contact BC connecting the cell active area ACT to the lower electrode 191, but does not include the node pad XP (in FIG. 1). The landing pad LP may be disposed between the buried contact BC and the lower electrode 191.

In detail, a lower cell insulating layer 135 may be formed on the substrate 100 and the cell element separation layer 105. More specifically, the lower cell insulating layer 135 may be disposed on the substrate 100 and the cell element separation layer 105 on which the bit line contact 146 is not formed. The lower cell insulating layer 135 may be disposed between the substrate 100 and the cell conductive line 140, and between the cell element separation layer 105 and the cell conductive line 140.

The lower cell insulating layer 135 may be a single layer or a multilayer including a first lower cell insulating layer 136 and a second lower cell insulating layer 137. For example, the first lower cell insulating layer 136 may include a silicon oxide layer, and the second lower cell insulating layer 137 may include a silicon nitride layer. Unlike illustrated in the drawing, the lower cell insulating layer 137 may also include three or more insulating layers.

A portion of the bit line contact 146 may be recessed into the cell conductive line 140. The upper surface 146US of the bit line contact may protrude higher than an upper surface of the lower cell insulating layer 135. Based on the upper surface of the cell element separation layer 105, a height of the upper surface 146US of the bit line contact is higher than a height of the upper surface of the lower cell insulating layer 135.

A plurality of storage contacts 120 may be disposed between the cell conductive lines 140 adjacent in the first direction DR1. The storage contact 120 may overlap the substrate 100 and the cell element separation layer 105 between the cell conductive lines 140 adjacent to each other. The storage contact 120 may be connected to the storage connection area 103b (in FIG. 2) of the cell active area ACT. Here, the storage contact 120 may correspond to the buried contact BC. The plurality of storage contacts 120 may include, e.g., at least one of a semiconductor material doped with impurities, a conductive metal silicide, a conductive metal nitride, a conductive metal carbide, a conductive metal carbonitride, a conductive metal oxide, a metal, and a metal alloy.

The storage pad 160 may be formed on the storage contact 120. The storage pad 160 may be electrically connected to the storage contact 120.

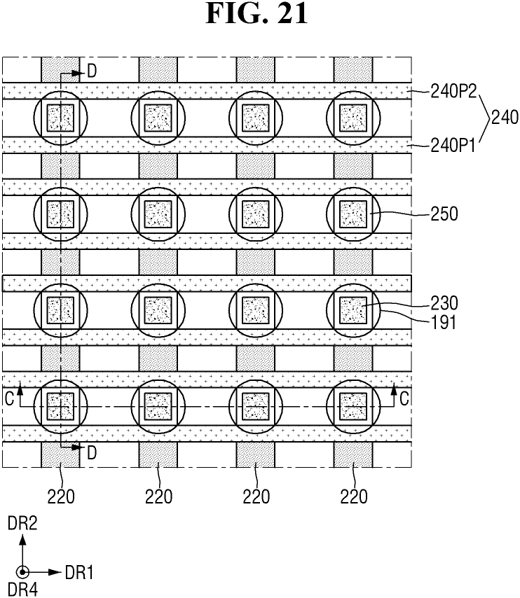

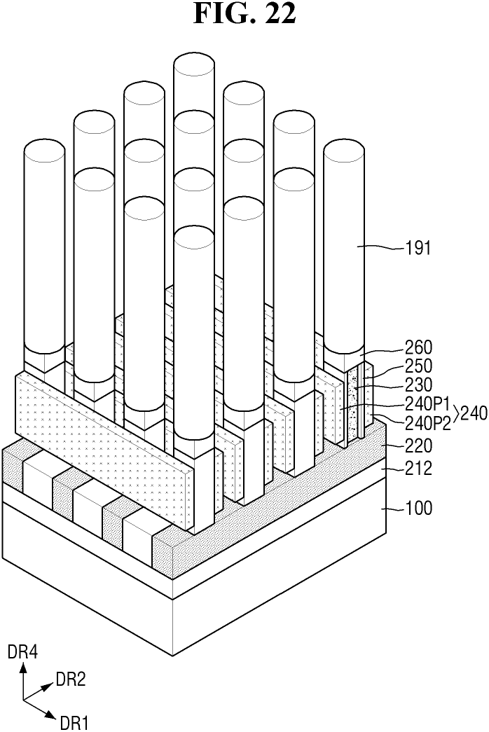

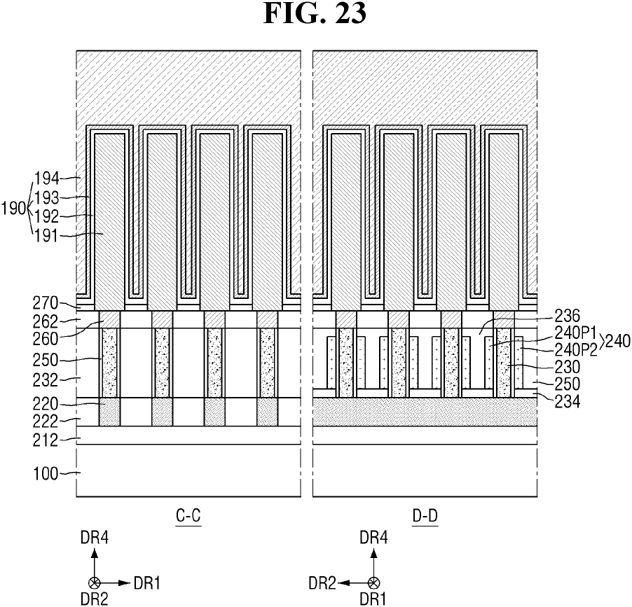

FIG. 21 is a layout view of a semiconductor memory device according to some exemplary embodiments. FIG. 22 is a perspective view of a semiconductor memory device according to some exemplary embodiments. FIG. 23 is a cross-sectional view taken along lines C-C and D-D of FIG. 21.

Referring to FIGS. 21 to 23, a semiconductor memory device according to some exemplary embodiments may include the substrate 100, a plurality of first conductive lines 220, a channel layer 230, a gate electrode 240, a gate insulating layer 250, and an information storage portion 480. The semiconductor memory device according to some exemplary embodiments may be a memory device including a vertical channel transistor (VCT). The VCT may refer to a structure in which a channel length of the channel layer 230 extends in a vertical direction from the upper surface of the substrate 100, e.g., along the fourth direction DR4.

A lower insulating layer 212 may be disposed on the substrate 100. The plurality of first conductive lines 220 may be spaced apart from each other in the first direction DR1 and extend in the second direction DR2 on the lower insulating layer 212. A plurality of first insulating patterns 222 may be disposed on the lower insulating layer 212 to fill a space between the plurality of first conductive lines 220. The plurality of first insulating patterns 222 may extend in the second direction DR2. Upper surfaces of the plurality of first insulating patterns 222 may be disposed at the same level as upper surfaces of the plurality of first conductive lines 220. The plurality of first conductive lines 220 may function as bit lines.

The plurality of first conductive lines 220 may include, e.g., a doped semiconductor material, a metal, a metal alloy, a conductive metal nitride, a conductive metal silicide, a conductive metal oxide, or a combination thereof. For example, the plurality of first conductive lines 220 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO, or a combination thereof. The plurality of first conductive lines 220 may include a single layer or multiple layers of the materials described above. In exemplary embodiments, the plurality of first conductive lines 220 may include, e.g., graphene, carbon nanotube, or a combination thereof.

The channel layer 230 may be arranged in a matrix form disposed to be spaced apart from each other in the first direction DR1 and the second direction DR2 on the plurality of first conductive lines 220. The channel layer 230 may have a first width in the first direction DR1 and a first height in the fourth direction DR4, and the first height may be greater than the first width. Here, the fourth direction DR4 intersects the first and second directions DR1 and DR2, and may be, e.g., a direction perpendicular to the upper surface of the substrate 100. For example, the first height may be about 2 times to about 10 times the first width. A bottom portion of the channel layer 230 may function as a first source/drain area, an upper portion of the channel layer 230 may function as a second source/drain area, and a portion of the channel layer 230 between the first and second source/drain areas may function as a channel area.

In exemplary embodiments, the channel layer 230 may include an oxide semiconductor. For example, the oxide semiconductor may include InGaZnO, InGaSiO, InSnZnO, InZnO, ZnO, ZnSnO, ZnON, ZrZnSnO, SnO, HfInZnO, GaZnSnO, AlZnSnO, YbGaZnO, InGaO, or a combination thereof. The channel layer 230 may include a single layer or multiple layers of the oxide semiconductor. In some examples, the channel layer 230 may have a bandgap energy greater than that of silicon. For example, the channel layer 230 may have a bandgap energy of about 1.5 eV to about 5.6 eV. For example, the channel layer 230 may have optimal channel performance when it has a bandgap energy of about 2.0 eV to 4.0 eV. For example, the channel layer 230 may be polycrystalline or amorphous. In exemplary embodiments, the channel layer 230 may include, e.g., graphene, carbon nanotube, or a combination thereof.

The gate electrode 240 may extend in the first direction DR1 on both sidewalls of the channel layer 230. The gate electrode 240 may include a first sub-gate electrode 240P1 facing a first sidewall of the channel layer 230, and a second sub-gate electrode 240P2 facing a second sidewall opposite to the first sidewall of the channel layer 230. For example, when one channel layer 230 is disposed between the first sub-gate electrode 240P1 and the second sub-gate electrode 240P2, the semiconductor memory device may have a dual gate transistor structure. In another example, when the second sub-gate electrode 240P2 is omitted and only the first sub-gate electrode 240P1 facing the first sidewall of the channel layer 230 is formed, a single-gate transistor structure may also be implemented. The material included in the gate electrode 240 may be the same as the description of the cell gate electrode 112.

The gate insulating layer 250 may surround the sidewall of the channel layer 230 and may be interposed between the channel layer 230 and the gate electrode 240. For example, as illustrated in FIG. 21, an entirety of the sidewall of the channel layer 230 may be surrounded by the gate insulating layer 250, and a portion of the sidewall of the gate electrode 240 may be in contact with the gate insulating layer 250. In other exemplary embodiments, the gate insulating layer 250 may extend in an extending direction of the gate electrode 240 (i.e., the first direction DR1), and only two sidewalls facing the gate electrode 240 among the sidewalls of the channel layer 230 may be in contact with the gate insulating layer 250. In exemplary embodiments, the gate insulating layer 250 may be formed of, e.g., a silicon oxide layer, a silicon oxynitride layer, a high-k material having a higher dielectric constant than that of the silicon oxide layer, or a combination thereof.

A plurality of second insulating patterns 232 may extend along the second direction DR2 on the plurality of first insulating patterns 222. The channel layer 230 may be disposed between two adjacent second insulating patterns 232 among the plurality of second insulating patterns 232. In addition, a first buried layer 234 and a second buried layer 236 may be disposed in a space between two adjacent channel layers 230 between the two adjacent second insulating patterns 232. The first buried layer 234 may be disposed on a bottom portion of the space between the two adjacent channel layers 230. The second buried layer 236 may be formed to fill the remainder of the space between the two adjacent channel layers 230 on the first buried layer 234. An upper surface of the second buried layer 236 may be disposed at the same level as an upper surface of the channel layer 230, and the second buried layer 236 may cover an upper surface of the gate electrode 240. In another example, the plurality of second insulating patterns 232 may be formed of a continuous material layer with the plurality of first insulating patterns 222, or the second buried layer 236 may be formed of a continuous material layer with the first buried layer 234.

A capacitor contact 260 may be disposed on the channel layer 230. The capacitor contacts 260 may be disposed to vertically overlap the channel layer 230 and may be arranged in a matrix form spaced apart from each other in the first direction DR1 and the second direction DR2. The capacitor contact 260 may be formed of, e.g., doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO, or a combination thereof. An upper insulating layer 262 may surround sidewalls of the capacitor contact 260 on the plurality of second insulating patterns 232 and the second buried layer 236.

A second etching stop layer 270 may be disposed on the upper insulating layer 262. The information storage portion 190 may be disposed on the second etching stop layer 270. The information storage portion 190 may include the lower electrode 191, the capacitor dielectric layer 192, the upper electrode 193, and the upper plate electrode 194. The lower electrode 191 may penetrate through the second etching stop layer 270 to be electrically connected to an upper surface of the capacitor contact 260. For example, the lower electrode 191 may be formed in a pillar type extending in the fourth direction DR4. For example, the lower electrode 191 may be disposed to vertically overlap the capacitor contact 260 and may be arranged in a matrix form spaced apart from each other in the first direction DR1 and the second direction DR2. In another example, a landing pad may be further disposed between the capacitor contact 460 and the lower electrode 191 so that the lower electrode 191 may also be arranged in a hexagonal shape.

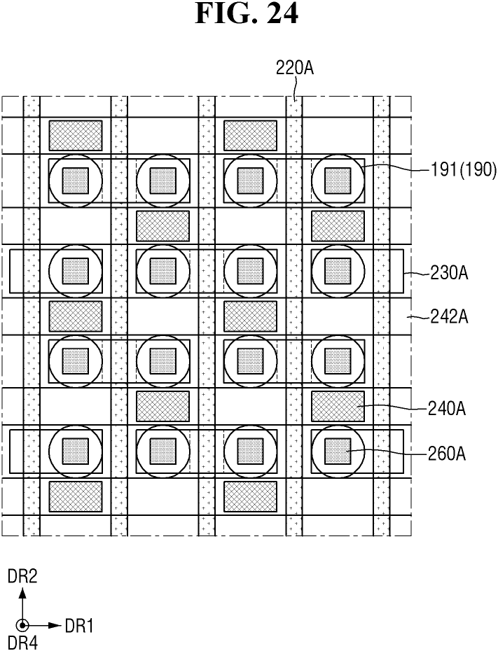

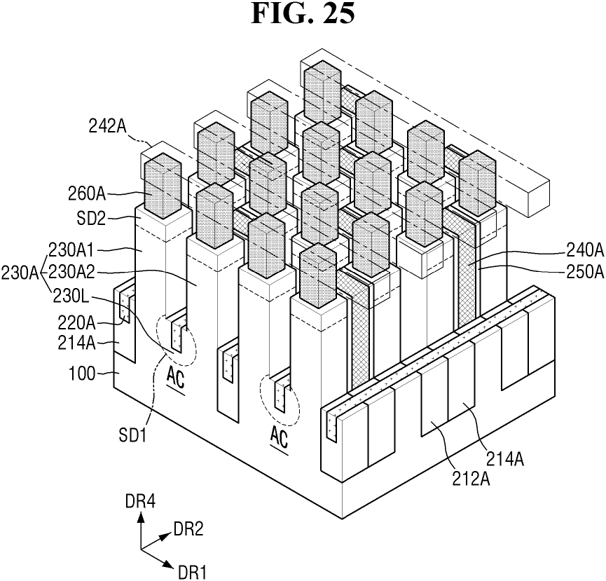

FIG. 24 is a layout view of a semiconductor memory device according to some exemplary embodiments. FIG. 25 is a perspective view of a semiconductor memory device according to some exemplary embodiments.

Referring to FIGS. 24 and 25, a semiconductor memory device according to some exemplary embodiments may include the substrate 100, a plurality of first conductive lines 220A, a channel structure 230A, a contact gate electrode 240A, a plurality of second conductive lines 242A, and the information storage portion 190. The semiconductor memory device according to some exemplary embodiments may be a memory device including a vertical channel transistor (VCT).

A plurality of active areas AC may be defined in the substrate 100 by a first element separation pattern 212A and a second element separation pattern 214A. The channel structure 230A may be disposed in each active area AC. The channel structure 230A may include a first active pillar 230A1 and a second active pillar 230A2 extending in a vertical direction, respectively, and a connection portion 230L connected to a bottom portion of the first active pillar 230A1 and a bottom portion of the second active pillar 230A2. A third source/drain area SD1 may be disposed in the connection portion 230L. A fourth source/drain region SD2 may be disposed on an upper side of the first and second active pillars 230A1 and 230A2. The first active pillar 230A1 and the second active pillar 230A2 may each constitute an independent unit memory cell.

The plurality of first conductive lines 220A may extend in a direction intersecting each of the plurality of active areas AC, e.g., in the second direction DR2. One first conductive line 220A of the plurality of first conductive lines 220A may be disposed on the connection portion 230L between the first active pillar 230A1 and the second active pillar 230A2. One first conductive line 220A may be disposed on the third source/drain area SD1. Another first conductive line 220A adjacent to one first conductive line 220A may be disposed between the two channel structures 230A. One first conductive line 220A of the plurality of first conductive lines 220A may function as a common bit line included in the two unit memory cells constituted by the first active pillar 230A1 and the second active pillar 230A2 disposed on both sides of the one first conductive line 220A.

One contact gate electrode 240A may be disposed between two channel structures 230A adjacent in the second direction DR2. For example, the contact gate electrode 240A may be disposed between the first active pillar 230A1 included in one channel structure 230A and the second active pillar 230A2 of the channel structure 230A adjacent thereto. One contact gate electrode 240A may be shared by the first active pillar 230A1 and the second active pillar 230A2 disposed on both sidewalls thereof. A fourth gate insulating layer 250A may be disposed between the contact gate electrode 240A and the first active pillar 230A1, and between the contact gate electrode 240A and the second active pillar 230A2. The plurality of second conductive lines 242A may extend in the first direction DR1 on an upper surface of the contact gate electrode 240A. The plurality of second conductive lines 242A may function as word lines of the semiconductor memory device.

A capacitor contact 260A may be disposed on the channel structure 230A. The capacitor contact 260A may be disposed on the fourth source/drain area SD2, and the information storage portion 190 may be disposed on the capacitor contact 260A.

By way of summation and review, in a highly scaled semiconductor element, a process of forming a plurality of wiring lines and a plurality of buried contacts interposed therebetween becomes increasingly complex and difficult. Therefore, aspects of the present disclosure provide a highly integrated semiconductor memory device with improved reliability and performance.

That is, according to embodiments, an upper plate electrode of a capacitor may include two or more layers with two or more boron doping concentrations, with one of the layers including boron having a mass number of 11. As the upper electrode plate doped with a high concentration of boron is disposed adjacent to the upper electrode of the capacitor, resistance between the upper plate electrode and the upper electrode may be reduced. Further, as the upper electrode plate doped with a high concentration of boron is disposed as the outermost layer, defects may be prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a substrate;
a landing pad on the substrate;
a lower electrode on and connected to the landing pad;
a dielectric layer on and extending along a profile of the lower electrode;
an upper electrode on the dielectric layer; and
an upper plate electrode on the upper electrode, the upper plate electrode including a first sub-plate electrode and a second sub-plate electrode doped with boron, a first concentration of the boron in the first sub-plate electrode being greater than a second concentration of the boron in the second sub-plate electrode.

2. The semiconductor memory device as claimed in claim 1, wherein the first sub-plate electrode is between the second sub-plate electrode and the upper electrode.

3. The semiconductor memory device as claimed in claim 2, wherein the upper plate electrode further includes a third sub-plate electrode doped with boron, a third concentration of the boron in the third sub-plate electrode being greater than the first concentration of the boron, and the third sub-plate electrode being between the first sub-plate electrode and the upper electrode.

4. The semiconductor memory device as claimed in claim 2, wherein the upper plate electrode further includes a third sub-plate electrode doped with boron, a third concentration of the boron in the third sub-plate electrode being greater than the second concentration of the boron, and the second sub-plate electrode being between the first sub-plate electrode and the third sub-plate electrode.

5. The semiconductor memory device as claimed in claim 1, wherein the second sub-plate electrode is between the first sub-plate electrode and the upper electrode.

6. The semiconductor memory device as claimed in claim 5, wherein the upper plate electrode further includes a third sub-plate electrode doped with boron, a third concentration of the boron in the third sub-plate electrode being greater than the first concentration of the boron, and the first sub-plate electrode being between the third sub-plate electrode and the second sub-plate electrode.

7. The semiconductor memory device as claimed in claim 5, wherein the upper plate electrode further includes a third sub-plate electrode doped with boron, a third concentration of the boron in the third sub-plate electrode being smaller than the first concentration, and the first sub-plate electrode being between the second sub-plate electrode and the third sub-plate electrode.

8. The semiconductor memory device as claimed in claim 1, further comprising a capping metal electrode on the upper plate electrode, the upper plate electrode being between the capping metal electrode and the upper electrode.

9. The semiconductor memory device as claimed in claim 8, further comprising a contact plug electrically connected to the upper plate electrode, the contact plug being on the capping metal electrode.

10. The semiconductor memory device as claimed in claim 8, further comprising a contact plug penetrating through the capping metal electrode and connected to the upper plate electrode.

11. The semiconductor memory device as claimed in claim 1, wherein the upper plate electrode includes a silicon plate electrode extending along a profile of the upper electrode, the silicon plate electrode including an undoped silicon layer.

12. The semiconductor memory device as claimed in claim 1, wherein each of the first sub-plate electrode and the second sub-plate electrode includes a silicon-germanium layer.

13. The semiconductor memory device as claimed in claim 1, wherein the boron includes a first boron having a mass number of 11 and a second boron having a mass number of 10.

14. A semiconductor memory device, comprising:
a substrate;
a landing pad on the substrate;
a lower electrode on and connected to the landing pad;
a dielectric layer on and extending along a profile of the lower electrode;
an upper electrode on the dielectric layer; and
an upper plate electrode on the upper electrode, the upper plate electrode including a silicon plate electrode and a silicon-germanium plate electrode, the silicon plate electrode including an undoped silicon layer, and the silicon-germanium plate electrode including a silicon-germanium layer doped with boron having a mass number of 11.

15. The semiconductor memory device as claimed in claim 14, wherein the silicon plate electrode is between the silicon-germanium electrode and the upper electrode.

16. The semiconductor memory device as claimed in claim 14, further comprising a capping metal electrode on the upper plate electrode, the upper plate electrode being between the capping metal electrode and the upper electrode.

17. The semiconductor memory device as claimed in claim 16, further comprising a contact plug electrically connected to the upper plate electrode, the contact plug being on the capping metal electrode.

18. The semiconductor memory device as claimed in claim 16, further comprising a contact plug penetrating through the capping metal electrode and connected to the upper plate electrode.

19. A semiconductor memory device, comprising:
a substrate including an active area defined by an element separation layer and extending in a first direction, the active area including a first portion and a second portion defined on both sides of the first portion;
a word line extending in a second direction different from the first direction and crossing between the first portion of the active area and the second portion of the active area in the substrate and the element separation layer;
a bit line contact connected to the first portion of the active area;
a bit line on the bit line contact, the bit line being connected to the bit line contact and extending in a third direction different from the first direction and the second direction; and
a capacitor connected to the second portion of the active area, the capacitor including:
a lower electrode connected to the second portion of the active area,
a dielectric layer extending along a profile of the lower electrode on the lower electrode,
an upper electrode on the dielectric layer, and
an upper plate electrode on the upper electrode and including a silicon plate electrode and a silicon-germanium plate electrode, the silicon-germanium plate electrode including a first sub-silicon-germanium plate electrode and a second sub-silicon-germanium plate electrode doped with boron, and a first concentration of the boron in the first sub-silicon-germanium plate electrode is greater than a second concentration of the boron in the second sub-silicon-germanium plate electrode.

20. The semiconductor memory device as claimed in claim 19, further comprising:
a capping metal electrode on the upper plate electrode, the upper plate electrode being between the capping metal electrode and the upper electrode; and
a contact plug electrically connected to the upper plate electrode.
